(19) United States
(12) Patent Application Publication
(10) Pub. No.: US 2009/0014318 A1
(43) Pub. Date: Jan. 15, 2009

(54) Phase-change material, sputter target comprising the phase-change material, method of forming phase-change layer using the sputter target, and method of manufacturing phase-change random access memory comprising the phase-change layer

(75) Inventor: Yoon-ho Khang, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/071,453

(22) Filed: Feb. 21, 2008

(30) Foreign Application Priority Data
Jul. 11, 2007 (KR) 10-2007-0069834

(51) Int. Cl. C23C 14/34; C01B 31/00; C23C 14/14

(52) U.S. Cl. 204/192.15; 423/445 B; 420/591; 204/298.13; 977/742; 977/902

(57) ABSTRACT

Provided is a phase change material, a sputter target including the phase change material, a method of forming a phase change layer using the sputter target, and a method of manufacturing a phase change memory device including the phase change layer formed using the method. The phase change material may include fullerene, and the sputter target may include the phase change material that includes fullerene.

### PRIORITY STATEMENT

This application claims priority under 35 U.S.C. §119 to Korean Patent Application No. 10-2007-0069834, filed on Jul. 11, 2007, in the Korean Intellectual Property Office (KIPO), the entire contents of which are incorporated herein by reference.

### BACKGROUND

1. Field

Example embodiments relate to a material that may be used in a sputter target, a sputter target including the material, a method of forming a thin film using the material as the sputter target, and a method of manufacturing a semiconductor device including a thin film formed using the method. Other example embodiments relate to a phase change material, a sputter target that includes the phase change material, a method of forming a phase change layer using the sputter target, and a method of manufacturing a phase change memory device including the phase change layer formed using the method of forming a phase change layer.

2. Description of the Related Art

A phase-change random access memory (PRAM) is a nonvolatile memory device, e.g., a flash memory, a ferroelectric RAM (FeRAM), and a magnetic RAM (MRAM). A structural difference between the PRAM and other nonvolatile memory devices is in a storage node. A storage node of the PRAM may include a phase change layer, a phase of which changes from an amorphous state to a crystalline state or vice versa according to given conditions. The resistance of the phase change layer may be relatively high when the phase change layer is in an amorphous state, and relatively low when the phase change layer is in a crystalline state. Thus, data is written or read using the resistance changing characteristics of the phase change layer.

Ge—Sb—Te (GST) layers may be used as the phase change layer in a PRAM, and from among the GST layers, a Ge₂Sb₂Te₅ layer may be used. However, because GST has relatively low activation energy, the data retention characteristics required by the PRAM may be difficult to meet. Thus, as a method of increasing the activation energy of GST, a method of doping a predetermined or given dopant has been suggested. However, because the dopant particles more easily agglomerate, obtaining a GST film in which the predetermined or given dopant particles are uniformly distributed may be more difficult. Also, in depositing the GST film doped with a dopant using a conventional technique, changes in the dopant concentration, the characteristics of the GST film, and the deposition speed may occur as the deposition process proceeds. For these reasons, forming a phase change layer having relatively high uniformity and relatively high phase change characteristics and manufacturing a PRAM that includes the phase change layer may be difficult.

### SUMMARY

To address the above and/or other problems, example embodiments provide a phase change material that may be used as a sputter target for forming a phase change layer having relatively high uniformity and relatively high phase change characteristics. Example embodiments also provide a sputter target that may include the phase change material. Example embodiments also provide a method of forming a phase change layer using the sputter target. Example embodiments also provide a method of manufacturing a phase-change random access memory (PRAM) that may include a phase change layer formed using the above method.

According to example embodiments, there is provided a phase change material comprising fullerene. The phase change material may include at least one of Ge, Sb, and Te. For example, the phase change material may be at least one of Ge—Sb—Te, Ge—Bi—Te, and In—Sb—Te. The fullerene may be at least one selected from the group consisting of C₆₀, C₇₀, C₇₄, C₇₆, C₇₈, C₈₂, C₈₄, and carbon nanotube. The content X (atom %) of the fullerene in the phase change material may be about 0<X≦ about 30.

According to example embodiments, there is provided a sputter target comprising a phase change material, wherein the phase change material includes fullerene. The phase change material may include at least one of Ge, Sb, and Te. For example, the phase change material may be at least one of Ge—Sb—Te, Ge—Bi—Te, and In—Sb—Te. The fullerene may be at least one selected from the group consisting of C₆₀, C₇₀, C₇₄, C₇₆, C₇₈, C₈₂, C₈₄, and carbon nanotube. The content X (atom %) of the fullerene in the sputter target may be about 0<X≦ about 30.

According to example embodiments, there is provided a method of forming a phase change layer using a sputtering method, wherein the sputter target used in the sputtering method may include a phase change material including fullerene. The sputter target may be formed of the phase change material including the fullerene.

The phase change material may include at least one of Ge, Sb, and Te. For example, the phase change material may be at least one of Ge—Sb—Te, Ge—Bi—Te, and In—Sb—Te. The fullerene may be at least one selected from the group consisting of C₆₀, C₇₀, C₇₄, C₇₆, C₇₈, C₈₂, C₈₄, and carbon nanotube. The content X (atom %) of the fullerene in the sputter target may be about 0<X≦ about 30.

According to example embodiments, there is provided a method of manufacturing a phase change memory device comprising a storage node that includes a phase change layer and a switching device connected to the storage node, wherein the phase change layer is formed using the method described above.

The sputter target may be formed of the phase change material including the fullerene. The phase change material may include at least one of Ge, Sb, and Te. For example, the phase change material may be at least one of Ge—Sb—Te, Ge—Bi—Te, and In—Sb—Te. The fullerene may be at least one selected from the group consisting of C₆₀, C₇₀, C₇₄, C₇₆, C₇₈, C₈₂, C₈₄, and carbon nanotube. The content X (atom %) of the fullerene in the sputter target may be about 0<X≦ about 30.

### BRIEF DESCRIPTION OF THE DRAWINGS

Example embodiments will be more clearly understood from the following detailed description taken in conjunction with the accompanying drawings. FIGS. 1-3 represent non-limiting, example embodiments as described herein.

FIG. 1 is a cross-sectional view of a phase change material structure according to example embodiments;

FIG. 2 is a schematic drawing showing a method of forming a phase change layer using a sputter target that includes a phase change material according to example embodiments; and

FIG. 3 is a schematic cross-sectional view for explaining a phase change memory device that includes a phase change layer formed according to the method of forming a phase change layer and a method of manufacturing the phase change memory device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

A phase change material, a sputter target that includes the phase change material, a method of forming a phase change layer using the sputter target, and a method of manufacturing a phase change memory device that includes a phase change layer formed according to the method according to example embodiments will now be described more fully with reference to the accompanying drawings in which example embodiments are shown. In the drawings, the thicknesses of layers and regions are exaggerated for clarity, and like reference numerals refer to like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view of a phase change material structure 100 according to example embodiments. Referring to FIG. 1, the phase change material structure 100 according to the example embodiments may include a phase change material layer 10 including fullerene 20. The phase change material layer 10 may include at least one of Ge, Sb, and Te. For example, the phase change material layer 10 may be one of Ge—Sb—Te, Ge—Bi—Te, In—Sb—Te, and a mixture thereof. The fullerene 20 may be in the form of a plurality of particles that may be uniformly distributed in the phase change material layer 10. The fullerene 20 may be at least one of C₆₀, C₇₀, C₇₄, C₇₆, C₇₈, C₈₂, C₈₄, and carbon nanotube, and the content X (atomic %) of the fullerene 20 in the phase change material structure 100 may be about 0<X≦ about 30.

The phase change material structure 100 may be formed by molding a mixture of particles of a phase change material and fullerene to a predetermined or given shape and annealing the mixture of the predetermined or given shape. Also, after grinding the phase change material structure 100 into powder, the powder may be remolded and annealed. The grinding operation, the molding operation, and the annealing operation may be repeatedly performed.

Chemical bonding between fullerene particles may be relatively weak. Also, the particle size of the fullerene 20 may be relatively small. For example, C₆₀ may have a diameter of only about 0.7 nm. Thus, the fullerene 20 may be uniformly distributed in the phase change material layer 10 without being granulated. The phase change material structure 100 in which the fullerene 20 is uniformly distributed in the phase change material layer 10 may be used as a sputter target for forming a phase change layer.

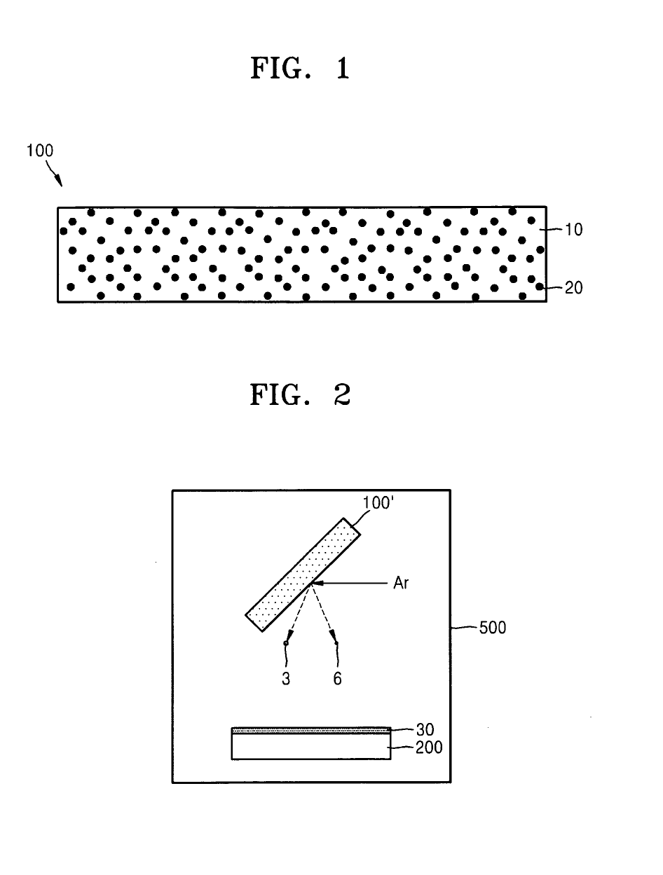

FIG. 2 is a schematic drawing showing a method of forming a phase change layer using the phase change material structure 100 as a sputter target. Referring to FIG. 2, after placing a sputter target 100′ equivalent to the phase change material structure 100 of FIG. 1 above a substrate 200 in a vacuum chamber 500, the sputter target 100′ may be sputtered using predetermined or given ions, for example, Ar ions. Due to the sputtering, phase change material atoms 3 and carbon C 6 may be emitted from the sputter target 100′ and deposited together on the substrate 200. As a result, a phase change layer 30, in which carbon C is doped, may be formed on the substrate 200. In the sputtering process, the substrate 200 may be heated above the ambient temperature by a predetermined or given heating means (not shown) connected to the substrate 200. When the process of forming the phase change layer 30 is completed, after the substrate 200 is replaced by another substrate, another deposition process for forming a phase change layer on another substrate may be performed. In this manner, phase change layers may be deposited on a plurality of substrates.

According to example embodiments, if the phase change material structure 100 of FIG. 1, in which the particles of the fullerene 20 having relatively small sizes and relatively weak chemical bonding force are uniformly distributed in the phase change material layer 10 is used as a sputter target, the phase change layer 30 having high uniformity of carbon C may be formed. Also, the problems of changing doping concentration of carbon C, changing characteristics of the phase change layer 30, and changing deposition speed, which are caused as the deposition process proceeds, may be prevented or reduced. Thus, when example embodiments are used, the phase change layer 30 having increased uniformity and relatively high phase change characteristics may be formed.

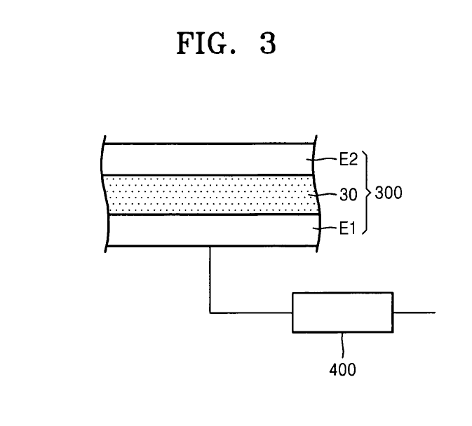

The method of forming the phase change layer 30 according to example embodiments described with reference to FIG. 2 may be applied to a method of forming a phase change layer of a PRAM. The method of forming a PRAM according to example embodiments will now be described with reference to FIG. 3.

FIG. 3 is a schematic cross-sectional view of a PRAM. Referring to FIG. 3, a storage node 300 may include a first electrode E1, a phase change layer 30, and a second electrode E2, which are sequentially stacked. One of the first and second electrodes E1 and E2, for example, the first electrode E1, may be connected to a switching device 400. The switching device 400 may be a transistor or another device, for example, a diode. In manufacturing the PRAM, the phase change layer 30 may be formed using the method described with reference to FIG. 2. The other constituent elements except the phase change layer 30 may be formed using a conventional method, and thus, the descriptions thereof will be omitted.

As described above, in example embodiments, because a phase change material structure that includes fullerene is used as a sputter target, a phase change layer having relatively high doping uniformity of carbon C may be obtained. For example, according to example embodiments, changes in the doping concentration of carbon C, the characteristics of the phase change layer, and deposition speed, which are caused as the deposition process proceeds, may be prevented or reduced. If the method of forming a phase change layer according to example embodiments is applied to a method of manufacturing a PRAM, reproducibility, reliability, and data retention characteristics may be increased.

While example embodiments have been shown and described with reference to embodiments thereof, it should not be construed as being limited to such embodiments. Those skilled in the art know, for example, that the structure and constituent elements of the PRAM of FIG. 3 may be modified. Therefore, the scope of example embodiments is not defined by the detailed description of example embodiments but by the appended claims.

What is claimed is:

1. A phase change material comprising fullerene.

2. The phase change material of claim 1, wherein the phase change material further includes at least one of Ge, Sb, and Te.

3. The phase change material of claim 2, wherein the phase change material is at least one of Ge—Sb—Te, Ge—Bi—Te, and In—Sb—Te.

4. The phase change material of claim 1, wherein the fullerene is at least one selected from the group consisting of C₆₀, C₇₀, C₇₄, C₇₆, C₇₈, C₈₂, C₈₄, and carbon nanotube.

5. The phase change material of claim 1, wherein the content X (atom %) of the fullerene in the phase change material is about 0<X≦ about 30.

6. A sputter target comprising the phase change material of claim 1.

7. The sputter target of claim 6, wherein the phase change material includes at least one of Ge, Sb, and Te.

8. The sputter target of claim 7, wherein the phase change material is at least one of Ge—Sb—Te, Ge—Bi—Te, and In—Sb—Te.

9. The sputter target of claim 6, wherein the fullerene is at least one selected from the group consisting of C₆₀, C₇₀, C₇₄, C₇₆, C₇₈, C₈₂, C₈₄, and carbon nanotube.

10. The sputter target of claim 6, wherein the content X (atom %) of the fullerene in the sputter target is about 0<X≦ about 30.

11. A method of forming a phase change layer by sputtering, wherein a sputter target used in the sputtering method comprises a phase change material including fullerene.

12. The method of claim 11, wherein the phase change material includes at least one of Ge, Sb, and Te.

13. The method of claim 12, wherein the phase change material is at least one of Ge—Sb—Te, Ge—Bi—Te, and In—Sb—Te.

14. The method of claim 11, wherein the fullerene is at least one selected from the group consisting of C₆₀, C₇₀, C₇₄, C₇₆, C₇₈, C₈₂, C₈₄, and carbon nanotube.

15. The method of claim 11, wherein the content X (atom %) of the fullerene in the sputter target is about 0<X≦ about 30.

16. A method of manufacturing a phase change memory device comprising a storage node including a phase change layer and a switching device connected to the storage node, wherein the phase change layer is formed using the method described in claim 11.

17. The method of claim 16, wherein the phase change material includes at least one of Ge, Sb, and Te.

18. The method of claim 17, wherein the phase change material is at least one of Ge—Sb—Te, Ge—Bi—Te, and In—Sb—Te.

19. The method of claim 16, wherein the fullerene is at least one selected from the group consisting of C₆₀, C₇₀, C₇₄, C₇₆, C₇₈, C₈₂, C₈₄, and carbon nanotube.

20. The method of claim 16, wherein the content X (atom %) of the fullerene in the sputter target is about 0<X≦ about 30.
